(19) United States
(12) Patent Application Publication
(10) Pub. No.: US 2014/0325818 A1
(43) Pub. Date: Nov. 6, 2014

(54) FILLED AMORPHOUS BAG APPARATUS FOR POSITIONING SCREENED DEVICES AND METHOD FOR THE USE THEREOF

(71) Applicant: GUI Global Products, Ltd., Houston, TX (US)

(72) Inventor: Walter G. Mayfield, Houston, TX (US)

(73) Assignee: GUI Global Products, Ltd., Houston, TX (US)

(21) Appl. No.: 14/230,450

(22) Filed: Mar. 31, 2014

Related U.S. Application Data
(60) Provisional application No. 61/818,272, filed on May 1, 2013.

(51) Int. Cl. H05K 5/02; F16M 11/00

(52) U.S. Cl. CPC H05K 5/0204; F16M 11/00
USPC 29/428; 206/525; 206/524.1; 206/457; 248/346.2

(57) ABSTRACT

A filled amorphous bag apparatus, similar to a “bean bag”, comprises at least one amorphous bag, a malleable filling within the amorphous bag, and at least one first connector on or within the amorphous bag. The malleable filling may include, but not be limited to, a plurality of pellets (e.g. beans), a putty, a gel, a stuffing (e.g. straw, cotton) and combinations thereof. The connector may be a magnet, a plurality of hooks, a plurality of loops, a suction cup, one half of a snap, a clip, a clamp, a clasp, and combinations of these. Optionally, first mating connector is a magnet and in another non-limiting embodiment the filled amorphous bag apparatus has a covering, where the connector is a magnet free to move around the surface of at least one amorphous bag between the at least one amorphous bag and the covering. Alternatively, a portion of a plurality of pellets making up the malleable filling may be magnetic or non-magnetic and ferrimagnetic or ferromagnetic. The bag itself may comprise optional features including a screen cleaning material, a duster material, a receptacle (e.g. a pocket), a strap and the like.

### CROSS REFERENCE TO RELATED APPLICATION

This application is claims priority from U.S. Provisional Patent Application Ser. No. 61/818,272 for “Filled Amorphous Bag Apparatus for Positioning Screened Devices and Method for the Use Thereof”, filed on May 1, 2013, the disclosure of which is incorporated herein by reference in its entirety.

### TECHNICAL FIELD

The present invention relates to apparatus and methods for adjusting the position of a screen of a screened device, where the invention more particularly relates to apparatus and methods for holding a screened device and adjusting the position of the screen of a screened device, which apparatus and devices having at least one first mating connector thereon.

### BACKGROUND

Beginning in the early years of the twenty-first century, a large variety of new screened devices have been developed and sold, including, but not necessarily limited to, mobile devices such as smart phones and tablet computers. Many of these portable electronic devices have a view screen for displaying text. Some of these devices also are used for displaying photographs and in some cases movies. The newest of these devices display photographs and movies in high definition. While some electronic devices such as digital picture frames, come with a mechanism such as a stand for positioning the screen for viewing, phones and tablet computers generally have not. However, often the original manufacturer and/or third parties sell separate stands for such devices.

With the advent of portable electronic devices, it has become common to observe such devices being used in many public venues and social settings. Such venues include coffee shops, restaurants, shopping malls, and the like. These devices can be seen in just about any public setting. It is often desirable for the screened device to be positioned vertically or at a generally vertical angle so that one or more people can view the same photograph, text or video being displayed. If the viewing time is extended, such as during the display of a long series of photographs, or a television show or movie, it is desirable to be able to position or prop the screened device into an orientation for viewing without a person holding it, to avoid the person becoming fatigued.

Mobile devices also provide instruction and direction in navigation. These devices may be dedicated GPS navigation systems or smart phones or tablet computers that have navigation software installed. There is a need to place such devices on or around a vehicle dashboard in positions that enable the driver to temporarily view and/or hear instructions from the device. Because the design and configuration of vehicle dashboards varies considerably from vehicle to vehicle, it would be helpful to have an apparatus and method that is easily and quickly adaptable from one vehicle to another.

It would thus be desirable in the art of supporting screened devices, if such devices could be positioned using an apparatus and method that is quickly and easily employed, which apparatus and method are simple and therefore are not costly.

### SUMMARY

In one non-limiting embodiment there is provided a filled amorphous bag apparatus for positioning screened devices, where the apparatus includes at least one amorphous bag, a malleable filling within the amorphous bag, and at least one first connector on or within the amorphous bag.

There is also provided, in another non-limiting form, a filled amorphous bag apparatus for positioning screened devices, where the apparatus includes at least one amorphous bag, a malleable filling within the amorphous bag, and at least one first connector that is a recess to receive an armature within the amorphous bag, where the armature is configured to be adjustable and positionable, and the armature comprises at least one second connector.

There is further provided in another embodiment a filled amorphous bag apparatus for positioning screened devices, the apparatus including at least one amorphous bag, a malleable filling within the amorphous bag, at least one rigid armature comprising at least one first connector.

In a different non-restrictive embodiment there is provided a multi-component system for positioning screened devices, where the multi-component system includes at least one mounting component configured to mount to a case of a screened device bearing a screen, the mounting component comprising a magnetic surface and a filled amorphous bag apparatus for positioning screened devices, where the apparatus includes at least one amorphous bag, a malleable filling within the amorphous bag, and at least one rigid armature comprising at least one first connector.

Additionally there is provided in another non-limiting version a method for positioning a screened device, where the method includes attaching a filled amorphous bag apparatus to the screened device, where the filled amorphous bag apparatus includes at least one amorphous bag, a malleable filling within the amorphous bag, and at least one first connector on or within the amorphous bag, where the method further includes adjusting the pellet-filled amorphous bag apparatus to position the screened device.

### BRIEF DESCRIPTION OF THE DRAWINGS

FIG. 1a is a three-quarters perspective view of one embodiment of a first part of a multi-component system, namely a mounting component, mounted on a case of a screened device;

FIG. 1b is a three-quarters perspective view a non-limiting embodiment of a second part of a multi-component system, namely a pellet-filled amorphous bag apparatus having at least one first connector thereon configured to selectively couple with the mounting component mounted on a case of a screened device of FIG. 1b, including a cut-away section of an at least one amorphous bag;

FIG. 1c is a three-quarters perspective view illustrating a non-limiting embodiment of the screened device of FIG. 1a in position on the at least one amorphous bag once the mounting component mounted on a case of a screened device is selectively coupled with the first connector of the pellet-filled amorphous bag apparatus of FIG. 1b;

FIG. 2a is a three-quarters perspective view of another non-restrictive version of the filled amorphous bag apparatus having a generally cylindrical shape with an optional strap thereon;

FIG. 2b is a three-quarters perspective view of another non-limiting embodiment of the filled amorphous bag apparatus having a generally cylindrical shape with optional end stabilizing elements and showing a screened device selectively coupled thereto oriented in portrait mode;

FIG. 2c three-quarters perspective view illustrating another non-restrictive version of the filled amorphous bag apparatus having a generally cylindrical shape with optional side stabilizing elements and showing a screened device selectively coupled thereto oriented in landscape mode;

FIG. 3 is a three-quarters perspective view of a different non-limiting embodiment of the filled amorphous bag apparatus having a generally cylindrical shape adapted to be inserted into a cup holder;

FIG. 4 is a three-quarters perspective view illustrating another non-restrictive version of the filled amorphous bag apparatus having at least one first connector therein which is a recess adapted to receive an amorphous, adjustable and positionable armature, and having an optional pocket;

FIG. 5 is a three-quarters perspective view illustrating a different non-limiting embodiment of the filled amorphous bag apparatus having an optional removable cover with has thereon an optional duster material and an optional screen cleaning material;

FIG. 6 is a three-quarters perspective view illustrating yet another alternative embodiment of the filled amorphous bag apparatus which is configured and shaped to have a concave recess in the underside thereof which adapts it to sit stably on a post or pedestal, such as a vehicle gear shift knob;

FIG. 7 is a three-quarters perspective view illustrating a different non-restrictive version of the filled amorphous bag apparatus having a generally cylindrical shape, one end of which has an optional, flat, weighted base;

FIG. 8 is a three-quarters perspective view illustrating another non-limiting embodiment of the filled amorphous bag apparatus which has an optional, flat base showing in hidden lines multiple positions of at least one magnetic first connector that may move underneath the surface of the apparatus;

FIG. 9 is a three-quarters perspective view illustrating in a different non-limiting embodiment a filled amorphous bag apparatus having a generally cylindrical shape having an optional first end and an independently optional second end, where the at least one amorphous bag has an average diameter, and where at least one end is a rigid end cap with a dimension greater than the average diameter of the at least one amorphous bag;

FIG. 10 is a three-quarters perspective view illustrating another non-restrictive version of the filled amorphous bag apparatus having a generally rigid, central, cylindrical shape showing two amorphous ends, where the rigid, central shape has a diameter, and where two amorphous “bean bag” ends have a dimension greater than the diameter of the rigid, central shape;

FIG. 11 is a cross-sectional illustration of a different non-limiting embodiment of the filled amorphous bag apparatus having a covering over the at least one amorphous bag, showing that a magnetic first connector may move between the covering and the at least one amorphous bag, except for the end regions thereof, in one non-restrictive version;

FIG. 12 is a three-quarters perspective view illustrating a different non-limiting embodiment of the filled amorphous bag apparatus which has an optional hemispherical shape and an optional flat base;

FIG. 13a is a three-quarters perspective view of another non-restrictive version of the filled amorphous bag apparatus having an optional spherical shape, where the at least one first connector is a plurality of magnetic pellets (shown in a cut away section) within the at least one amorphous bag;

FIG. 13b illustrates the spherical filled amorphous bag apparatus of FIG. 13a that has been flattened;

FIG. 14 is a side view illustrating a cross-sectional side view of a vehicle windshield and a side view of a vehicle rear view mirror having a filled amorphous bag apparatus positioned thereon selectively coupled to a screened device, where the filled amorphous bag apparatus optional has a strap thereon to more securely hold it to the rear view mirror;

FIG. 15 is a three-quarters perspective view of a non-limiting embodiment of the amorphous bag apparatus where the filler is a moldable putty and the at least one amorphous bag is of a clear material;

FIG. 16 is a three-quarters perspective view illustrating non-restrictive embodiment of the amorphous bag apparatus where the at least one amorphous bag is in the shape of a doll or figure such as a puppy dog and the filling is a stuffing;

FIG. 17 is a three-quarters perspective view showing another non-limiting embodiment of the at least one amorphous bag apparatus where the at least one amorphous bag has the shape of doll or figure such as a monkey and the filling is a stuffing, shown in a removable position hanging from a vehicle rear view mirror; and

FIG. 18 is a three-quarters perspective view showing a different non-limiting embodiment of the amorphous bag apparatus having an elongated shape with an amorphous, adjustable and positionable armature thereon.

It will be appreciated that the various Figures are not necessarily to scale and that certain features have been exaggerated for clarity and do not necessarily limit the features of the invention.

### DETAILED DESCRIPTION

It has been discovered that an adjustable apparatus of a relatively simple and compact design may be used to position a screened device in a wide variety of contexts so that the screen may be more easily seen by one or more viewers without one of the viewers having to physically hold the device. The adjustable apparatus is configured to be a stand and to selectively and removably couple to at least one case using at least one first connector, optionally a magnetic attractive force. For the purposes of this application, the term “at least one case” means the primary case used by a manufacturer to hold and protect the individual electronic and other components of which a screened device is composed, but it can also mean a protective case that functions to protect the primary case. For example, a smartphone generally comprises electronics disposed within a rigid shell-like case. This would be the primary case. There are available protective cases, often made of leather, rubber, polymer elastomer, even wood, and/or rigid or flexible plastic, that serve to prevent scratches and blemishes on the primary case and sometimes to impart a bit of shock resistance as well.

The term “screened device” includes devices having a view screen including, but not limited to cell phones, smartphones, GPS navigators, some cameras, some telescopes, some weapons scopes, tablet computers, laptop computers, portable DVD players, digital photograph frames, portable electronic game players, digital music players (e.g. iPOD® player) and the like. Other non-limiting examples include computer monitors, televisions, laboratory apparatus (both portable and non-portable), mobile devices to collect and/or analyze data, and the like. While it is expected that the adjustable apparatus will find its greatest use in positioning electronic screened devices, the apparatus may also position mechanical screened devices including, but not necessarily limited to, devices that children and others may draw on such as an Ohio Art ETCH A SKETCH®, an Ohio Art DOODLE SKETCH™ (where the screen is wiped clean by a lever), a Magic Slate pad, or other drawing device with a screen or the like. Since the images on these non-electronic devices are static, the multi-component system or adjustable apparatus may serve as a display stand. The method of this application may be used with any screened device having a view screen.

The term “selectively couple” describes the process wherein an adjustable apparatus described herein is applied to a screened device and adheres to it because of a physical force, e.g. a magnetic force. The at least one first connector includes, but is not necessarily limited to, a magnet, a plurality of hooks, a plurality of loops, a suction cup, one half of a snap, a clip, a clamp, a clasp, adhesive, at least one recess, and combinations of these. In some cases, only a first connector is required, for instance a suction cup. In the case of adhesive, the adhesive should be of the removable and repositionable kind, such as the type well-known for use on sticky notes, in contrast to stronger adhesives that are permanent and not repositionable or not removable.

Clips, clamps and clasps may be envisioned that also only require a first connector (e.g. spring clips, hair clips, and the like), but others exist that require a second connector, in which case the first and second connectors are mating connectors that each require the other for the adjustable apparatus and the screened device to selectively couple. In a non-limiting instance a plurality of loops and a plurality of hooks, when properly sized relative to each other, can when placed together physically selectively couple with one another. A well-known example of loop-and-hook fasteners is a VELCRO® fastener. Of course, loop and hook connectors must be used in mated pairs and are ineffective on their own. Snaps are similar in that there must be a male and female snap to engage as a mated pair. While the apparatus and methods will be generally described herein where the at least one first connector is a magnet, it will be appreciated that these other coupling embodiments may also be employed.

In the case of a magnet in one non-limiting embodiment, there is sufficient magnetic force to allow the adjustable apparatus to remain in place despite casual movements of the electronic device, but to still be easily removed by a human operator. Hence, the coupling is selectable.

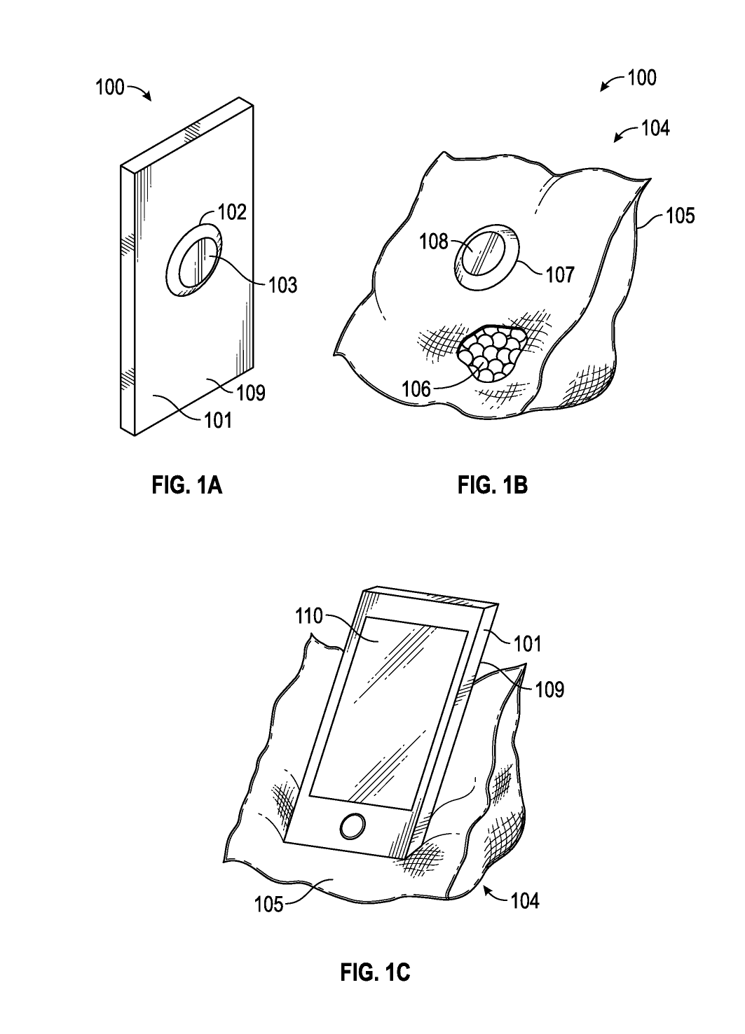

Shown in FIG. 1 is a three-quarters view of a screened device 101 such as a tablet computer, mobile device, etc. having a mounting component 102 affixed to the back side 109 of device 101, mounting component having a magnet 103 thereon, in one non-limiting embodiment. A filled amorphous bag apparatus 104 is shown in FIG. 1b, where the apparatus 104 comprises at least one amorphous bag 105 having a malleable filling 106 therein, and at least one first connector 107 on or within the amorphous bag 105, in this non-restrictive case on the bag 105 surface. At least one first connector 107 has a magnet surface 108 thereon, configured to selectively couple with the magnet 103 of the mounting component 102 of mobile device 101; for instance magnet 103 and magnet 108 may be of opposite polarity so that they may selectively couple together. The at least one first connector 107 may be rotatable or pivotable so that the mobile device 101 mounted thereon may be rotated, such as from portrait to landscape orientation, without reattaching the mobile device 101 to the apparatus 104. This may be true of any of the connectors shown in the various embodiments of the Figures. In the particular embodiment illustrated in FIG. 1b, the malleable filling 106 includes a plurality of pellets such as, but not necessarily limited to, beans, other dried organic materials (e.g. rice or other grains or granular materials) plastic pellets such as polyvinylchloride (PVC), expanded polystyrene, expanded polypropylene, sand, rocks, pebbles, metal shot, granular or particulate synthetic materials (e.g. the afore-mentioned and other polymers) and the like. All or a portion of the pellets may be non-magnetic ferrimagnetic material, non-magnetic ferromagnetic material, magnetic ferrimagnetic material, non-magnetic ferromagnetic material and combinations thereof. All of these materials give some weight to the apparatus for stability. Water and other liquids may also be used as a weighting material, however, such liquids should be contained within a liquid impervious, but amorphous container such as a bag or bladder. Such a bag or bladder may also be necessary in the case where the malleable filler is a gel, but it may not be necessary for some gels. It will be appreciated that the malleable filler for all of the embodiments shown in the Figures and discussed herein may be any of these alternatives.

In one non-restrictive embodiment, filled amorphous bag apparatus 104 resembles a conventional “bean bag”. FIG. 1c is a three-quarters view of mobile device 101 having its mounting component 102 selectively coupled with first connector 107 of the filled amorphous bag apparatus 104, and filled amorphous bag apparatus 104 is shaped to support the screened device 101 so that the screen may be viewed.

Amorphous bag apparatus 104 is not positionable in the same manner as a wire that holds its shape when moved, but can be shaped to a degree and does settle by gravity into a shape that can hold screened device 101 until it is moved or disturbed by an outside influence. It will be appreciated that the malleable filling 106 at least substantially fills at least one amorphous bag 105, but should not fill it so tightly that the amorphous bag apparatus 104 cannot be shaped to hold screened device 101 in a generally upright or generally vertical position for viewing. It should be noted that although the screen 110 of the screened device 101 may be positioned so that it is 90° or at a right angle to the support surface that it is sitting on (i.e. a table, vehicle dashboard, etc.), that it is not necessary for the screen 110 to be exactly at this angle, but that the angle of the back side 109 of the screened device 101 may be at a less than 90° angle, i.e. an acute angle. It will be appreciated that the position and shape of amorphous bag apparatus 104 may be adjusted without repositioning the device 101 on the apparatus 104.

As used herein, the term “amorphous” means lacking a definite permanent shape; that is, the amorphous bag apparatus may change shape, it has no set shape, and while it may be shaped by the user to some extent, it is not bendable or posable, such as in the sense that a wire or a wire core apparatus is bendable or posable.

Other connector types may be used for first connector 107 and mounting component 102 (and other connectors and mounting components described herein), besides magnets, for instance, a plurality of hooks, a plurality of loops (used together as VELCRO®-type fasteners), a suction cup, one half of a snap, a clip, a clamp, a clasp, adhesive, a recess, etc., the mounting component 102 may be at least one second connector to mate with the at least one first connector 107 on the amorphous bag apparatus 104. Throughout the Figures mounting components (e.g. 102) and magnetic surfaces (e.g. 108) are shown as having a circular shape, but this is merely a convenient shape (different reference numerals are used for the connectors in other Figures besides FIGS. 1a, 1b and 1c). Their shapes may be the same or different from each other (in the case where there are more than one) and may include, but not necessarily be limited to, circles, ovals, squares, rectangles, triangles, pentagons, pyramids, rhombuses, even decorative shapes such as flowers, stars, moons, etc. In one non-limiting embodiment the magnetic surface 108 is flat to maximize its contact with the magnet 103, which may also be flat in one non-restrictive version.

The magnets and magnetic surfaces (such as 103 and 108 in non-limiting examples) may be ferrimagnetic or ferromagnetic and may comprise iron or other conventional ferrimagnetic or ferromagnetic substance. More specifically, the magnetic bead may have or include at least one metal, such as but not limited to MnBi, MnAl, MnAlC, alloys of MnBi, alloys of MnAl, alloys of MnAlC, barium hexaferrite, strontium, neodymium, hexaferrite, NdFeB, alloys of NdFeB, samarium cobalt magnetic materials, alloyed cobalt materials, hard magnetic nitride materials, hard magnetic carbide materials, or rare earth magnetic materials, iron, iron-cobalt alloys, or iron-based alloys including silicon steel, nickel iron permalloys, iron-cobalt-vanadium alloys, or high saturation soft ferrite materials and combinations thereof.

The magnets or magnetic surfaces may optionally have a coating, such as but not limited to a metallic plating, an epoxy resin, plastic, and combinations thereof, or almost any coating to prevent oxidation of the magnets and/or reduce the brittleness of the magnets. In a non-limiting embodiment, the metallic plating may be or include metals, such as but not limited to gold, nickel, zinc, tin, silver, and combinations thereof. This type of metallic plating, as well as other magnet coatings mentioned, may protect the magnet under specific external conditions, such as but not limited to temperature changes, pressure changes, pH changes, corrosion, and the like. The magnet coating may also increase or decrease the magnetic force of the magnet. Additionally, the coating may be a thin shock absorbing material for absorbing some of the shock to the magnetic device and/or the magnets; the coating may have a force dampening effect. Such an effect may protect brittle magnets. When pellets 106 are of sufficient weight, such as of the ferrimagnetic or ferromagnetic material or other sufficiently dense material, such weight adds heft and stability to the apparatus 104.

In one non-restrictive version, the pellets 106 themselves may be the at least one first connector, where the pellets are any of the magnetic or non-magnetic ferrimagnetic or ferromagnetic materials noted above. It is not necessary that all of the pellets 106 be magnetic or non-magnetic ferrimagnetic or ferromagnetic materials, simply that enough of them are of these materials so that they may serve the purpose as at least one first connector. Of course, it is acceptable if all of the pellets 106 are of this material.

Mounting component 102 may be permanently, semi-permanently or temporarily affixed to the back side 109 of the case of screened device 101, or to a secondary, after-market case that at least partially covers the original manufacturer's case for screened device 101. An adhesive may be used for permanently affixing mounting component 102, for instance an epoxy, “super glue” (cyanoacrylate adhesive) or other permanent adhesive. Semi-permanently affixing the mounting component 102 may be done using the types of removable, repositionable adhesives used for “sticky notes” such as POST-IT® notes from 3M. Mounting component 102 may also be affixed using conventional means such as clips, brackets, screws, snaps and the like.

It will be further appreciated that both magnetic surface 103 of mounting component 102 and magnetic surface 108 need not be both be magnetic, although at least one of them should be and they both may be (in the non-limiting case of magnetic connectors). Magnetic surfaces 103 and 108 may be any of the materials noted previously as suitable or may simply have enough iron so that magnetic surfaces 103 and 108 may be selectively coupled or attached to each other. Of course, the poles of the magnetic surface 103 and magnetic bead 108 should be of opposite polarity for the two components to selectively couple together or attach. Mounting component 102 should be mounted on the screened device 101 in any location that permits the filled amorphous bag apparatus 104 to perform the desired function.

It should be also appreciated that amorphous bag or cover 105 may also be made of an iron alloy, magnetic or non-magnetic, but electrically conductive material. That is, amorphous bag apparatus 104 may additionally include an electrically conductive feature selected from the group consisting of the plurality of pellets 106 (i.e. malleable filling) and the at least one amorphous bag 105, and the at least one first connector is configured to electrically connect a mobile device to the electrically conductive feature to enhance the antenna of the mobile device for better Wi-Fi, cellular phone signal or other signal reception.

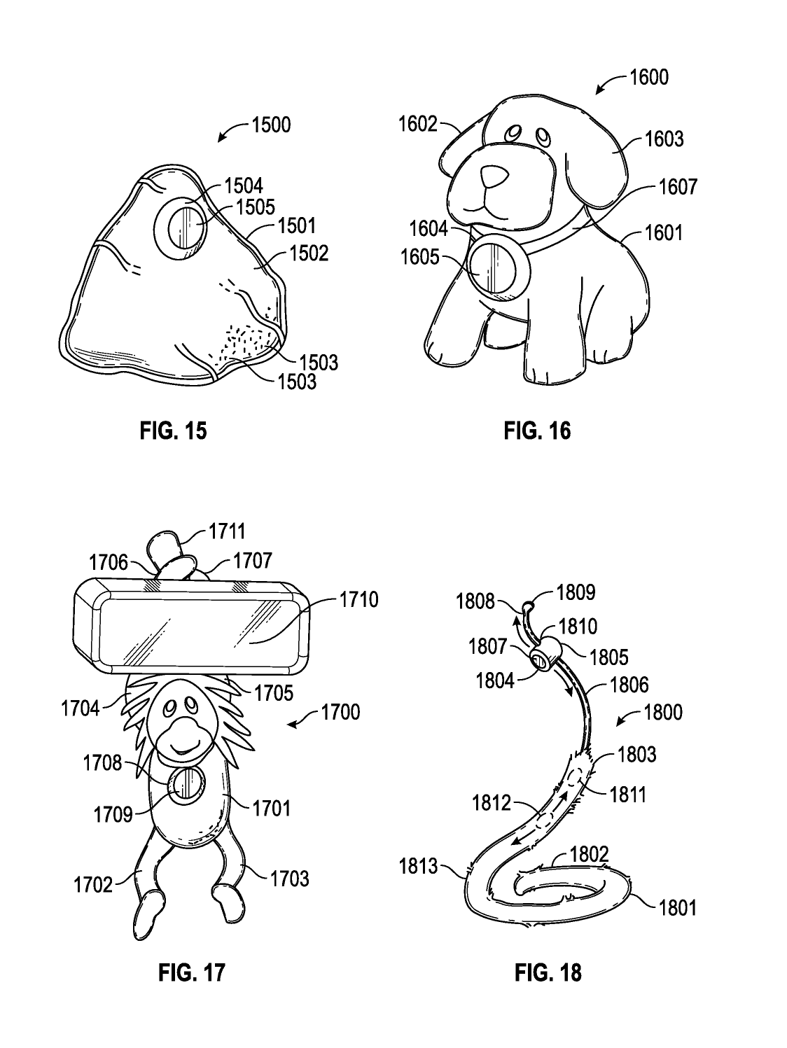

In another non-limiting embodiment FIG. 15 is a three-quarters perspective view of an amorphous bag apparatus 1500 having a transparent or translucent amorphous bag 1501 through which can be seen a filling 1502 that is malleable, and which may be a putty, such as a silicone putty or a clay putty, or which may be a gel. The putty or gel may have a plurality of iron-alloy or magnetic particles which may serve as the at least one first connector, which particles are schematically illustrated at 1503. In addition thereto, or alternatively thereto, amorphous bag apparatus 1500 may have at least one first connector 1504, optionally bearing a magnet 1505 thereon. Optionally, the putty or gel 1502 may be heat sensitive and have components which change the color of the putty or gel 1502 in response to changes in temperature, including being warmed by human touch. In another non-restrictive version, the amorphous bag 1501 may be water impervious to protect the filling 1502 and the iron and or magnetic particles 1503 from moisture and consequent corrosion. Non-transparent amorphous bags of other embodiments discussed elsewhere herein may also be made water impervious.

Malleable filling 106 may also be stuffing, such as that commonly used in stuffed animals, figures and the like, which stuffing may include, but is not necessarily limited to, straw, beans, feathers, cotton, polyester or other conventional synthetic fabric, combinations thereof and the like.

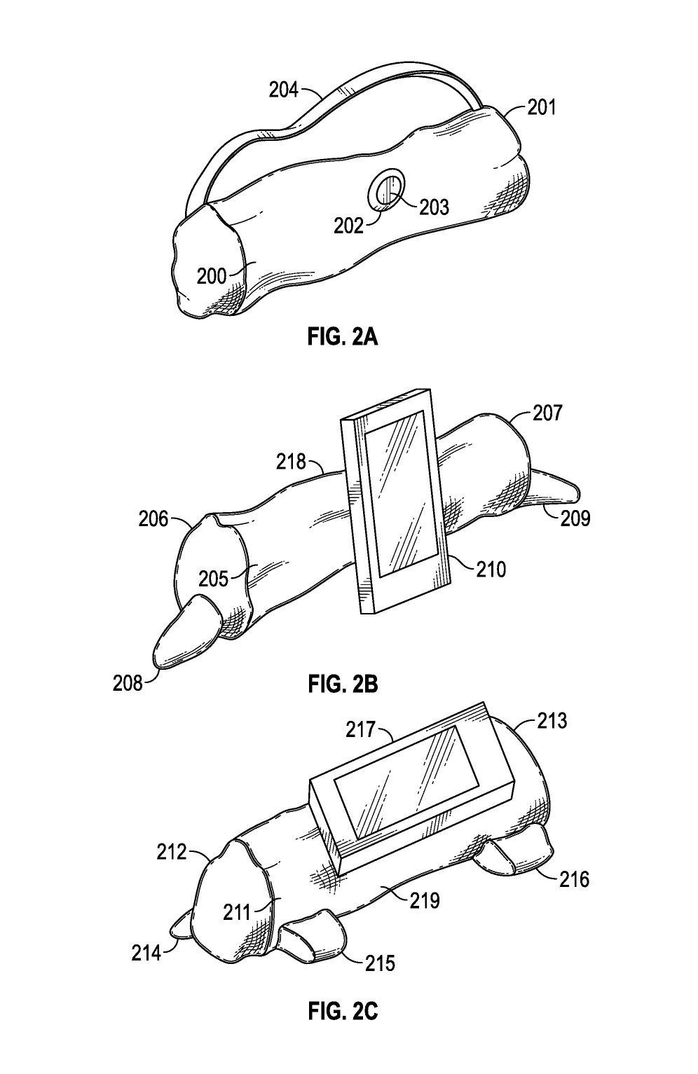

In another non-restrictive embodiment of the invention, the amorphous bag apparatus may have a cylindrical shape, such as seen in FIGS. 2a, 2b, 2c, 3, 4, 5, 7, 8, 9, 10 and 11. The cylindrical shape permits the apparatus or stand 200 to be rotated around its longitudinal axis. More specifically, FIG. 2a is a three-quarters perspective view of an amorphous bag apparatus 200 having at least one amorphous bag 201 enclosing a malleable filling (not shown) and at least one first connector 202 with a magnetic surface 203. The amorphous bag apparatus 200 has an optional strap 204 that may be used to carry the amorphous bag apparatus 200 or to secure the amorphous bag apparatus 200 to an object to hang it therefrom, such as a vehicle rear view mirror (please see FIG. 14 discussed in more detail below), or a light fixture or bathroom mirror or the like. It will be appreciated that the strap need not be connected to the amorphous bag 201 at the points shown, and may have a different configuration, for instance its length may be adjustable, such as is well known of straps on conventional purses and bags. Alternatively, optional strap 204 may be selectively coupled to filled amorphous bag apparatus 200 by a mechanism including, but not necessarily limited to, buttons, snaps, zippers, clips, clamps, hook-and-eye closures, hook-and-loop fasteners (e.g. VELCRO®-like fasteners), and the like.

Shown in FIG. 2b is a three-quarters perspective view of a filled amorphous bag apparatus 205 with at least one amorphous bag 218 and a malleable filling (not shown) having a generally cylindrical shape having a first end 206 and a second end 207, with optional end stabilizing protrusions 208 and 209 on the respective ends and showing a screened device 210 selectively coupled thereto oriented in portrait mode. By “generally cylindrical” is meant that the apparatus has a longitudinal axis and a generally circular cross-section and a first and second generally flat ends, recalling that, like a bean bag, the apparatus will sag under gravity and not have a true cylindrical shape with an exactly circular cross-section throughout its length and flat, circular ends.

Shown in FIG. 2c is a three-quarters perspective view of a filled amorphous bag apparatus 211 having a generally cylindrical shape having a first end 212 and a second end 213, as well as an amorphous bag 219, with optional end stabilizing protrusions 214, 215 and 216 on the respective ends and showing a screened device 217 selectively coupled thereto oriented in landscape mode. There may be a fourth end stabilizing protrusion on second end 213 that is hidden from view.

It will be appreciated that stabilizing protrusions 208, 209, 214, 215 and 216 may be amorphous or of a rigid or fixed shape. These stabilizing protrusions 208, 209, 214, 215 and 216 may be helpful to keep the amorphous bag apparatus in a particular position while it is holding a screened device. In a non-limiting instance, the FIG. 2b embodiment of amorphous bag apparatus 205 may be suitable for holding a screened device 210 on a steering column for viewing by a driver. It could also be imagined that the stabilizing protrusions may be of such a relative size to the at least one amorphous bag to which they are connected that they would form a second amorphous bag (or even a third or a fourth) with its respective malleable filling, to serve as part of the amorphous bag apparatus, likely providing additional stability. It will also be appreciated that screened devices used with amorphous bags 200, 205 and 211 may be oriented in portrait orientation or landscape orientation, and are not limited to the orientations shown in FIGS. 2b and 2c.

It will be appreciated that throughout this description herein, a screened device may be generally oriented in either landscape (horizontal) position or portrait (vertical) position, or at any angle in most of the embodiments even though there is not a separate illustration showing the screened device in both portrait and landscape position for every illustrated embodiment.

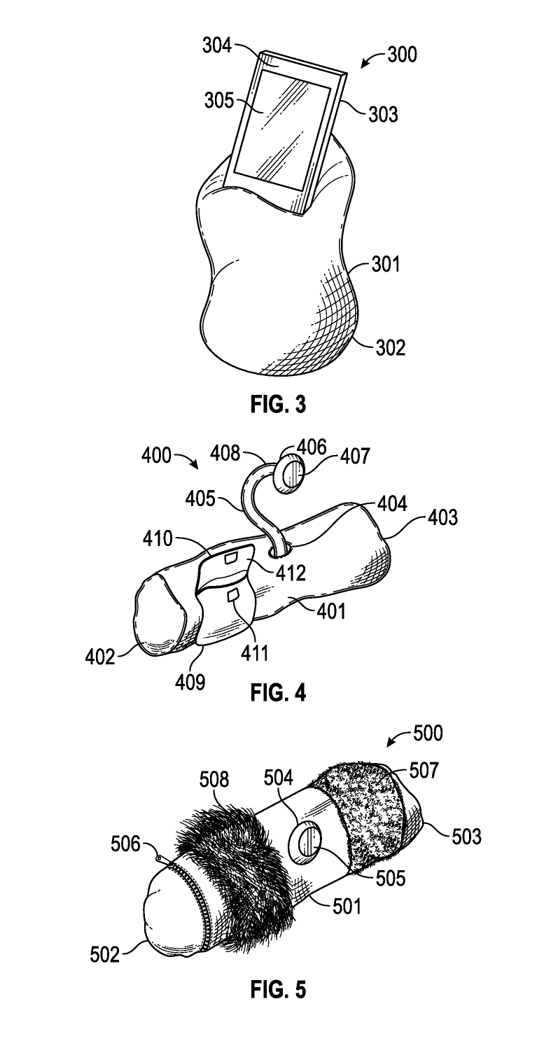

Shown in FIG. 3 is another non-limiting embodiment of the amorphous bag apparatus 300 having an at least one amorphous bag 301 that has a malleable filling (not shown), where the amorphous bag apparatus 300 is configured to be received within a cup holder, such as in a vehicle. In such a configuration, amorphous bag apparatus 300 has a base 302 that fits inside a conventional cup holder. It also has at least one first connector, which is hidden from view in FIG. 3 because it is selectively coupled to the mounting component on the back side 303 of screened device 304. In this embodiment amorphous bag apparatus 300 can hold screened device 304 so that the screen 305 thereof may be displayed, such as to the driver or passenger of a vehicle that has a cup holder.

It should also be appreciated that other embodiments shown in the Figures may function reside in a cup holder while also hold a screened device for viewing, including but not necessarily limited to, the embodiments of FIGS. 2a, 2b and 2c, 4, 5, 7, 8, 9, 10, and 11, all when the cylindrically-shaped apparatus is oriented in a vertical orientation.

Shown in FIG. 4 is a three-quarters perspective view of another non-restrictive version of the amorphous bag apparatus 400 having a cylindrical shape, at least one amorphous bag 401, a malleable filling (not shown), a first end 402 and a second end 403. In amorphous bag apparatus 400, the at least one first connector 404 is a recess to receive an armature 405, where the armature 405 is configured to be adjustable and positionable, and the armature 405 itself comprises at least one second connector 406 which may itself comprise a flat magnetic surface 407 in one non-limiting embodiment. Amorphous, elongated armature 405 may be adjustable and positionable, and posable or configurable, by which is meant once the armature 405 is posed or positioned, the position is held and maintained until a force acts upon it to change the pose or configuration. This may be accomplished by having a sufficiently strong wire core (not shown) of metal or other suitable material that is flexible and adjustable, but posable and configurable. The wire core may be encased or covered in rubber or polymer elastomer or other water-impervious material to protect the metal wire from the elements and prevent corrosion, but also to protect the user from the possible sharp ends of the wire core. By “amorphous armature” is meant lacking a definite, permanent shape; that is, the armature 405 can change shape, it has no set shape, it is bendable and posable. The amorphous, elongated armature 405 may have a constant exterior diameter and cross-sectional shape; in one non-limiting embodiment circular, as for conventional coated wire. However, alternatively the diameter and/or cross-sectional area and/or cross-sectional shape may vary along the length thereof and the cross-sectional shape may also vary along its length.

The amorphous, elongated armature 405 has a length with a first end (not shown, since it is within recess 406) and a second end 408 and at least one connector which, in one non-restrictive version, may be a magnetic bead 406 on the armature. Magnetic bead 406 may optionally slide at least partially along the length of armature 405, although it may be frictionally held in place once positioned. The exact position of the at least one magnetic bead 406 on the armature 405 may differ from one application or use to the next. In one non-limiting embodiment the magnetic bead 406 may have a flat side to engage other magnetic surfaces over a greater surface area for a more secure selective coupling thereto.

In another non-restrictive embodiment the at least one magnetic bead 406 is configured to slide or move along substantially the length of the armature 405 and configured to be positionable substantially along the length of the armature 405. By “substantially the length of the armature 405” is meant that most of the length of armature 405 may be traversed by the bead 406. By “positionable” is meant that the bead 406 will stay at its position on the armature 405 until a force moves it from that position. As previously described, the amorphous, elongated armature 405 may also be understood as positionable. In one non-limiting embodiment the magnetic bead is frictionally positionable, in one non-limiting instance the coating or covering on the armature 405 is a friction fit to the inside bore of a hole through the bead 406. The tolerances of the armature 405 diameter and the hole diameter would be such that when forced the bead would slide or move, but when the force is released the bead 406 would stay in place. This is a well-known phenomenon when the coating or covering is an elastomer that can be compressed during movement, but which expands back to its usual position or shape (or as close as possible within the hole) so that the bead 406 is held frictionally in place on the armature 405.

Alternatively, the position of the bead 406 on armature 405 may be held using another mechanism, including, but not necessarily limited to, a screw, pin, spring-actuated stop, clamp, or other structure known in the art.

Also shown in FIG. 4 is an optional receptacle 409 on amorphous bag 401, which in one non-limiting embodiment is a pocket having a flap 410, which may be optionally fastenable or closable, using any of a variety of closure mechanisms 411 and 412, including, but not necessarily limited to, magnets, a plurality of hooks and a plurality of loops (that is, a VELCRO® fastener type), a hook-and-eye, a snap, a button and button-hole, a clip, a clamp, a clasp, repositionable adhesive, and the like and combinations of these. The one or more receptacle 409 may be adapted to contain a wide variety of objects including, but not necessarily limited to, ear buds, a phone charger, electrical cords, glasses, writing implements (pen, pencil, etc.), a stylus, a Bluetooth device, a clock, keys, lipstick, breath mints, etc. The receptacle 409 may be of any shape or design or size or position and is not necessarily limited to the shape, position or relative size shown.

Shown in FIG. 5 is another, alternate amorphous bag apparatus 500 having at least one amorphous bag 501 containing a malleable filling (not shown), which apparatus 500 is also of a cylindrical shape with a first end 502 and a second end 503 and at least one first connector 504 with a magnetic surface 505. In this embodiment, bag 501 may be removable from the malleable filling (which may be of any type, but in one convenient form may be one-piece, such as putty or gel), such as by unzipping zipper 506. Alternatively, the bag 501 is open-ended, similar to a sock. This would be convenient to wash bag 501 should it become soiled. The closure device holding bag 501 on malleable filling does not have to be a zipper 506, but may be any convenient closure including, but not necessarily limited to, snaps, buttons, hooks, hooks-and-loops, and the like and combinations thereof.

One amorphous bag 501 may be optionally provided with one or more cleaning surfaces, including, but not necessarily limited to a screen cleaning material such as a microfiber cloth 507 and the like, as well as duster material 508, such as a fluffy duster for dusting a vehicle dashboard or the like, or optionally a brush or feather duster for such a purpose. In other non-limiting embodiments, the entire at least one amorphous bag 501 of this embodiment or any of the embodiments shown in the Figures may optionally be entirely made out of a screen cleaning material or a duster material.

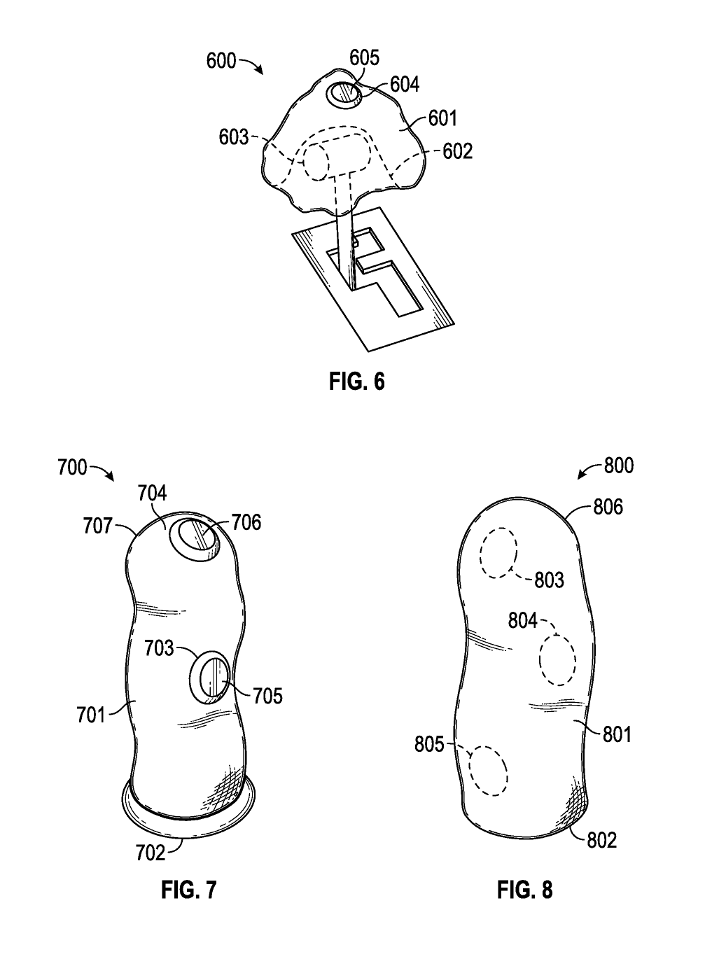

Shown in FIG. 6 is another non-limiting embodiment of the amorphous bag apparatus 600 having at least one amorphous bag 601 which encompasses and contains a malleable filling (not shown), which amorphous bag apparatus 600 may be formed and configured to have a concave recess 602, such as to receive a convex structure, including, but not necessarily limited to, a gear shift 603 of a vehicle. Amorphous bag apparatus 600 may have at least one first connector 604 with optionally a magnetic surface 605.

Shown in FIG. 7 is a three-quarters perspective view illustrating a different non-restrictive version of the filled amorphous bag apparatus 700 with at least one amorphous bag 701 containing and encompassing a malleable filling (not shown), which apparatus 700 has a generally cylindrical shape one end of which has an optional, flat base 702 upon which apparatus 700 stands, which base may be optionally weighted. Filled amorphous bag apparatus 700 may have a rounded top 707. Filled amorphous bag apparatus 700 is shown having two connectors, 703 and 704 (the latter being on or near rounded top 707), each of which has its own magnetic surface, 705 and 706, respectively.

FIG. 8 presents a three-quarters perspective view illustrating another non-limiting embodiment of the filled amorphous bag apparatus 800 with at least one amorphous bag 801 encompassing and containing a malleable filling (not show) which apparatus 800 has an optional, flat base 802, a rounded top 806, and showing in hidden lines multiple positions of at least one magnetic connectors 803, 804, and 805 that may move underneath the surface of bag 801 of the apparatus 800 for added versatility in the positioning of a screened device. Magnetic connectors 803, 804, and 805 may be fixed in place or optionally may move in their positions as explained next with respect to the FIG. 11 embodiment.

FIG. 11 shows a cross-sectional illustration of a different non-limiting embodiment of the filled amorphous bag apparatus 1100 having a covering 1102 over the at least one amorphous bag 1101, showing that a magnetic first connector 1103 may move between the covering 1102 and the at least one amorphous bag 1101, such as in directions indicated by the arrows. In the embodiment shown in FIG. 11 the first end 1104 and second end 1105 of the bag 1101 are attached to first end 1106 and second 1107, respectively of the covering 1102, in one non-restrictive version. Thus, magnetic connector 1103 cannot travel over the first and second ends 1104 and 1105. However, it may be readily imagined that such attachments do not exist and the magnetic connector 1103 may travel over the entire surface of amorphous bag 1101 underneath covering 1102. It may be further understood that filled amorphous bag apparatus 1100 may function well if the clearance between amorphous bag 1101 and covering 1102 is sufficiently close so as to keep magnetic connector 1103 in a flat orientation to the surface of the amorphous bag 1101; this will enable the connector on the back of the screened device to more readily connect thereto under the influence of one or more of the magnetic fields in the connector. It will be appreciated that the feature of a first connector such as a magnet 1103 sliding beneath a covering 1102 may be adapted for other of the various embodiments shown in the Figures and otherwise imagined. This embodiment of a magnetic connector moving beneath the cover or covering may be implemented on most of the configurations shown in the various Figures.

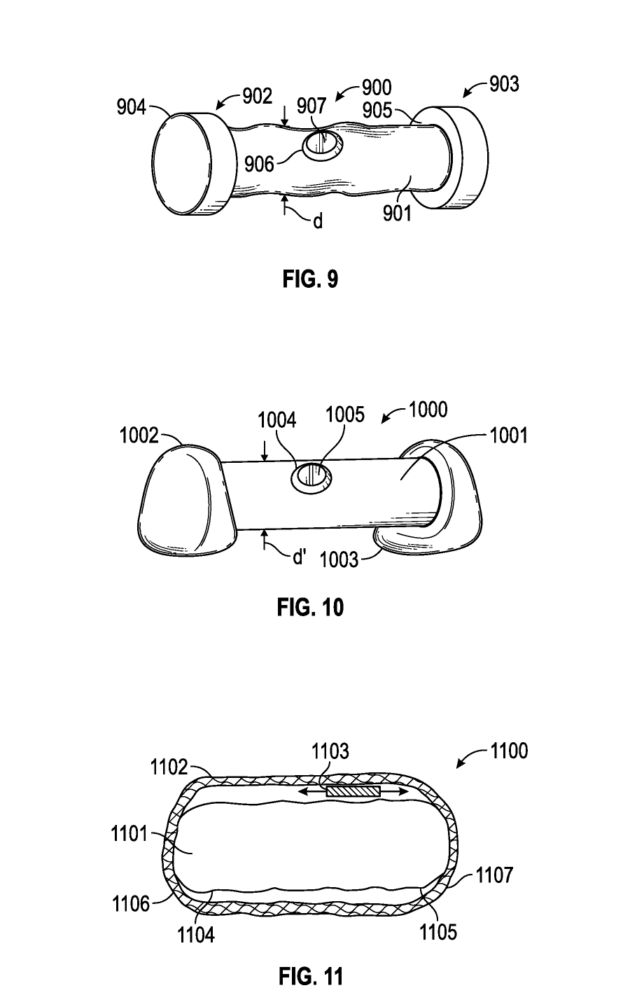

Shown in FIG. 9 is a three-quarters perspective view illustrating in a different non-limiting embodiment a filled amorphous bag apparatus 900 having a generally cylindrical shape with at least one amorphous bag 901 encasing or containing a malleable filling (not shown), the apparatus 900 having an optional first end 902 and an independently optional second end 903, where the at least one amorphous bag 901 has an average diameter d, and where at least one end is a rigid end cap 904 with a dimension greater than the average diameter d of the at least one amorphous bag 901. In another optional embodiment, second end 903 will also have a respective rigid end cap 905. In this way, the end caps 904 and 905 permit more stability with more weight, and with a larger diameter on the ends may raise the screened device higher off the surface or table. In this embodiment, the amorphous bag 901 is in the center and end caps 904 and 905 are rigid. Although end caps 904 and 905 are shown to be cylindrical, they may be of other shapes, in non-limiting instances, may have a triangular, pyramidal, square, cubic, rectangular or other suitable shape. Amorphous bag 901 has a first connector 906, which may have a magnetic surface 907.

FIG. 10 illustrates a three-quarters perspective view illustrating another non-restrictive version of the filled amorphous bag apparatus 1000 having a generally rigid, central, cylindrical section or armature 1001 showing a first amorphous end 1002 surrounding a malleable filing (not shown) and a second amorphous end 1003 also surrounding a malleable filing (not shown), where the rigid, central section or armature 1001 has a diameter d′, and where two amorphous “bean bag” ends 1002 and 1003 have a dimension greater than the diameter d′ of the rigid, central section 1001. Filled amorphous bag apparatus 1000 has a first connector 1004 with a magnet surface 1005 on the rigid central armature section 1001. Similarly to the embodiment shown in FIG. 9, the amorphous ends 1002 and 1003 of filled amorphous bag apparatus 1000 permit more stability with more weight, and with a larger dimension on the ends 1002 and 1003 may raise the screened device higher off the support surface or table. The central section 1001 does not have to have a cylindrical shape, but may be of any other suitable shapes including, but not limited to, an arc, an ovoid (“football”), sphere, rectilinear and the like, and may have a different cross-section than a circle, including, but not necessarily limited to, a triangle, a rectangle, a square, an oval, and the like.

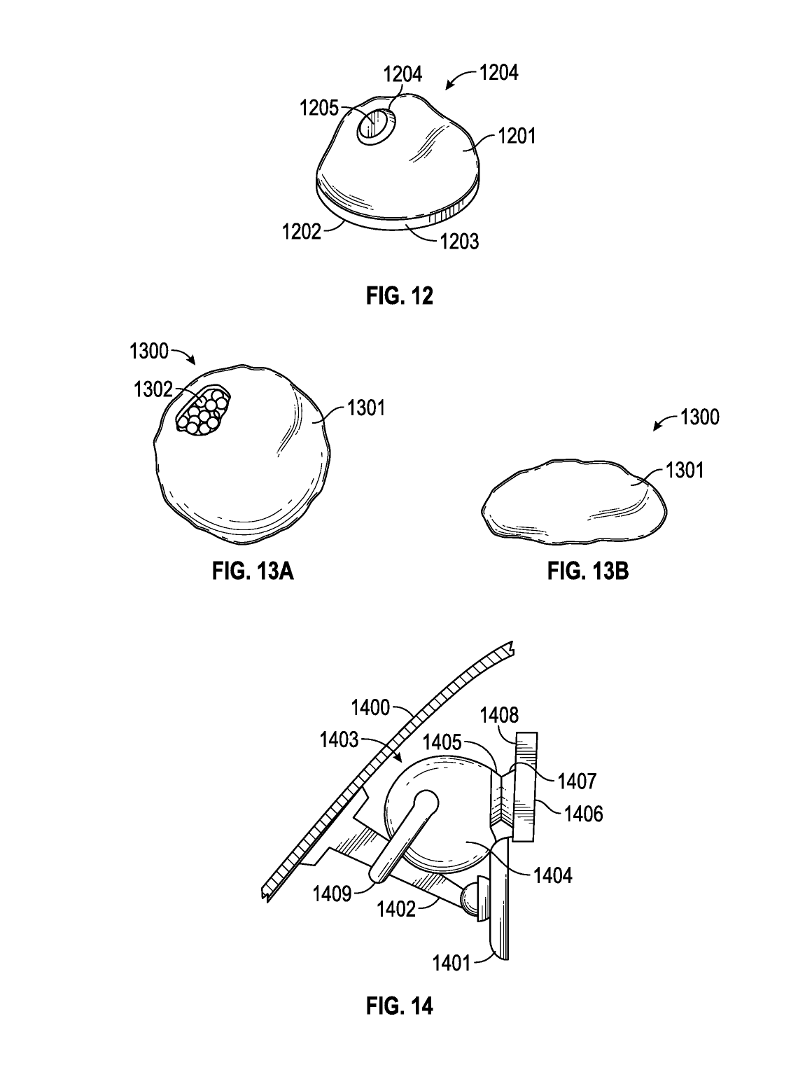

Shown in FIG. 12 is a three-quarters perspective view illustrating a different non-limiting embodiment of the filled amorphous bag apparatus 1200 which has an optional hemispherically-shaped outer bag 1201 and an optional flat base 1202. A malleable filling (not shown) would be contained within hemispherically-shaped outer bag 1201 Optional flat base 1202 may have a weighted structure 1203 to provide added stability. First connector 1204 bearing a magnetic surface 1205 may be in any suitable location, such as on or near the top of the hemispherical outer shape 1201.

FIG. 13a illustrates a three-quarters perspective view of another non-restrictive version of the filled amorphous bag apparatus 1300 having at least one amorphous bag 1301 in an optional spherical shape, where the malleable filling comprises at least one first connector 1302 are a plurality of magnetic pellets (shown in a cut-away section) within the at least one amorphous bag 1301. The magnetic pellets 1302 should have sufficient magnetic strength so that a mounting component 102 on the back side 105 of a screened device, such as 101 shown in FIG. 1a, would selectively couple via magnetic attraction thereto through the at least one amorphous bag 1301. Since the entire malleable filling of magnetic pellets 1302 may serve as the first connector, the screened device 101 may be placed anywhere on filled amorphous bag apparatus 1300, and the apparatus 1300 may be formed around it to serve as a suitable stand for device 101. As discussed above, it is not necessary for all of the pellets 1302 to be magnetic for the apparatus 1300 to function as intended. As shown in FIG. 13a, the filled amorphous bag apparatus 1300 generally has its spherical shape without having been otherwise formed. If the amorphous bag apparatus 1300 is flattened, it will have an appearance similar to that shown in FIG. 13b.

FIG. 14 is a side view illustrating a cross-sectional side view of a vehicle windshield 1400 and a side view of a vehicle rear view mirror 1401 affixed to windshield 1400 with mount 1402, where a filled amorphous bag apparatus 1403 having an amorphous cover 1404 containing a malleable filling (not shown) is positioned on the mirror 1401 and mount 1402, the apparatus 1403 being selectively coupled by first connector 1405 to a screened device 1406 via its own mounting component 1407 on the back side 1408 thereof. The filled amorphous bag apparatus 1403 optionally has a strap 1409 thereon to more securely hold it to the rear view mirror mount 1402. Strap 1408 may be a loop whose length is adjustable by any conventional means known in the art, such as in the art of purses and bags. The strap 1409 may include two separate lengths that may be tied together by their ends, or may be joined or connected by a mechanism including, but not necessarily limited to, at least one magnet, a combination of a plurality of hooks and a plurality of loops, a suction cup, a snap, a clip, a clamp, a clasp, adhesive, and combinations of these.

Shown in FIG. 16 is a three-quarters perspective view illustrating another non-restrictive embodiment of the amorphous bag apparatus 1600 where the at least one amorphous bag 1601 is in the shape of a puppy dog and the malleable filling (not shown) is a conventional stuffing for a stuffed animal, including, but not necessarily limited to, straw, cotton, feathers, dried beans, polyester or other synthetic fiber, and the like. Of course, it will be appreciated that the malleable filling may also or alternatively be any of the malleable fillings previous described. In the amorphous bag apparatus 1600 of FIG. 16, ears 1602 and 1603 may also be understood as amorphous bags having malleable filling (e.g. stuffing).

It should also be appreciated that although the amorphous bag apparatus 1600 depicted in FIG. 16 resembles a toy puppy dog and the amorphous bag apparatus 1700 depicted in FIG. 17 resembles a toy monkey, that neither these apparatus nor others depicted or discussed are limited to these particular toys or figures. The amorphous bag apparatus may be designed or configured to represent any suitable toy, figure, figurine, mascot, doll, action figure, logo, design, or object that would appeal to the consumer, whether resembling an actual or a fictional creature or object.

In this particular FIG. 16 embodiment the first connector 1604 having a magnetic surface 1605 thereon may be integrated into a collar 1607 for the stuffed animal puppy dog 1600. A screened device, such as that shown as 101 in FIGS. 1a and 1c, may selectively couple via its mounting component 102 to first connector 1604, and amorphous bag apparatus 1600 may thus display the screen 110 of device 101 in either landscape or portrait orientation.

Further, the amorphous bag apparatus 1700 shown in FIG. 17 in a three-quarters perspective view illustrates another non-limiting embodiment where the at least one amorphous bag 1701 has the shape of a toy monkey and the malleable filling (not shown) is again a type including those previously discussed, including a stuffing of conventional type. Amorphous bag apparatus 1700 has amorphous bag legs 1702 and 1703 and amorphous bag arms 1704 and 1705, with hands 1706 and 1707, respectively. A first connector 1708 having a magnetic surface 1709 is present on the “chest” of the monkey figure (amorphous bag 1701) in one non-limiting position. As shown in FIG. 17, amorphous bag apparatus 1700 is in a removable position hanging from a vehicle rear view mirror 1710, where the hands 1706 and 1707 attach to or link to one another around mirror mount 1711. The arms 1704 and 1705, and hands 1706 and 1707 thus function as a strap, and may be linked or connected by any known means or mechanism, including but not necessarily limited to, at least one magnet, a combination of a plurality of hooks and a plurality of loops (e.g. a VELCRO® fastener type), a suction cup, a snap, a clip, a clamp, a clasp, adhesive, and combinations of these. A screened device, such as device 101 of FIG. 1a may thus be supported on amorphous bag apparatus 1700 by selectively coupling the first connector 1708 with the mounting component 102 on the back side 109 of device 101 to hold the screen 110 in landscape or portrait orientation, for instance for use as a GPS navigator, hands-free smartphone, digital thermometer or other device in convenient view of the driver and/or passenger. It will be appreciated that a similar arrangement may help engage or attach a screened device to another structure, including but not necessarily limited to, a bathroom mirror or light, a computer monitor, a structure in a workshop, or the like. It will be appreciated that the amorphous bag apparatus is not limited to the shape of a dog shown in FIG. 16 or a monkey shown in FIG. 17, but may be designed to be one of any number of characters, animals, figures and the like.

Shown in FIG. 18 is a three-quarters perspective view of another non-restrictive version of the filled amorphous bag apparatus 1800 having an elongated, generally cylindrical shape, at least one amorphous bag 1801, a malleable filling (not shown, but which may be any of those previously discussed), a first end 1802 and a second end 1803. In amorphous bag apparatus 1800, the at least one first connector 1804 is on a sliding bead 1805, which slides substantially along the entire length of a positionable, amorphous armature 1806 in the direction of the adjacent arrows, where the armature 1806 is configured to be adjustable and positionable, and the armature 1806 itself comprises is integral to and part of the rest of apparatus 1800, unlike the removable armature 405 of the FIG. 4 embodiment. Connector 1804 may itself comprise a flat magnetic surface 1807 in one non-limiting embodiment. Amorphous bag 1801 may have an adjustable and positionable core (not shown), adjustable and positionable similar to a wire, along part or all of its length, and part of amorphous bag 1801 may not have such an adjustable and positionable core, but instead may be looser and more amorphous, for the lack of such a core; that is, more similar to a “bean bag”.

Amorphous, elongated armature 1806 may be adjustable and positionable, and posable or configurable, by which is meant once the armature 1806 is posed or positioned, the position is held and maintained until a force acts upon it to change the pose or configuration. This may be accomplished by having a sufficiently strong wire core (not shown) of metal or other suitable material that is flexible and adjustable, but posable and configurable. Again, the wire core may be encased or covered in rubber or polymer elastomer or other water-impervious material to protect the metal wire from the elements and prevent corrosion, but also to protect the user from the possible sharp ends of the wire core. By “amorphous armature” is meant lacking a definite, permanent shape; that is, the armature 1806 can change shape, it has no set shape, it is bendable and posable. The amorphous, elongated armature 1806 may have a constant exterior diameter and cross-sectional shape; in one non-limiting embodiment circular, as for conventional coated wire, as seen in FIG. 18. However, alternatively the diameter and/or cross-sectional area and/or cross-sectional shape may vary along the length thereof and the cross-sectional shape may also vary along its length.

The amorphous, elongated armature 1806 has a length with a first end (not shown, since it is within and/or integral with amorphous bag 1801) and a second end 1808 and at least one first connector 1804 which, in one non-restrictive version, may be at least one sliding bead 1805 on the armature 1806. Bead 1805 may optionally slide at least partially along the length of armature 1806, although it may be frictionally held in place once positioned. The exact position of the at least one bead 1805 on the armature 1806 may differ from one application or use to the next. In one non-limiting embodiment the bead 1805 may have a flat magnetic surface 1807 to engage other magnetic or non-magnetic (but ferrimagnetic or ferromagnetic) surfaces over a greater surface area for a more secure selective coupling thereto. There may be a restraint feature 1810 on the second end 1809 to keep sliding bead 1805 from sliding off of the armature 1806.

In another non-restrictive embodiment the at least one magnetic bead 1805 is configured to slide or move along substantially the length of the armature 1806 and configured to be positionable substantially along the length of the armature 1806. By “substantially the length of the armature 1806” is meant that most of the length of armature 1806 may be traversed by the bead 1805. By “positionable” is meant that the bead 1805 will stay at its position on the armature 1806 until a force moves it from that position. As previously described, the amorphous, elongated armature 1806 may also be understood as positionable. In one non-limiting embodiment the magnetic bead is frictionally positionable, in one non-limiting instance the coating or covering on the armature 1806 is a friction fit to the inside bore of a hole 1810 through the bead 1805. The tolerances of the armature 1806 diameter and the hole diameter would be such that when forced the bead 1805 would slide or move, but when the force is released the bead 1805 would stay in place. This is a well-known phenomenon when the coating or covering is an elastomer that can be compressed during movement, but which expands back to its usual position or shape (or as close as possible within the hole) so that the bead 1805 is held frictionally in place on the armature 1806.

Alternatively, the position of the bead 1805 on armature 1806 may be held using another mechanism, including, but not necessarily limited to, a screw, pin, spring-actuated stop, clamp, or other structure known in the art.

Also shown in FIG. 18 are at least one secondary connector 1811, although a tertiary connector 1812 is also shown. Secondary connector 1811 and tertiary connector 1812 are shown in dashed lines because they are underneath a covering 1813 of amorphous bag 1801, and are permitted to freely move beneath covering 1813, as suggested by the adjacent arrows. These connectors are similar to the embodiments discussed in FIGS. 8 and 11 to which attention is directed. Covering 1813 may also optionally completely or partially be one of the screen cleaning materials or dusting materials previously discussed.

It should be further understood that apparatus 1800 may be positionable to sit on a table to hold a screened device thereon, or may be configured to hang from a rear view mirror, handle, sun visor, or an overhead compartment in a vehicle, or from an overhead lamp or a bathroom mirror; alternatively wrapped around a gear shift or other lever, or the like.

It will be appreciated that the amorphous bag apparatus may include any number of amorphous bags and connectors thereto to selectively couple to one or more magnetic surfaces on one or more mounting components placed in various positions on one or more screened devices. It will also be appreciated that the multi-component system and/or adjustable apparatus as described herein may also be provided with an apparatus for cleaning view screens and lenses as described in PCT International Publication No. WO 2013/022768 A2, incorporated by reference herein in its entirety.

In the foregoing specification, the invention has been described with reference to specific embodiments thereof, and has been described as effective in providing adjustable methods and adjustable devices for positioning screened devices. However, it will be evident that various modifications and changes can be made thereto without departing from the broader spirit or scope of the invention as set forth in the appended claims. Accordingly, the specification is to be regarded in an illustrative rather than a restrictive sense. For example, specific designs and/or shapes and/or numbers of amorphous bags, malleable fillings, connectors, mounting components, straps, shown but not specifically identified or tried in a particular method or device, are expected to be within the scope of this invention.

The present invention may suitably comprise, consist or consist essentially of the elements disclosed and may be practiced in the absence of an element not disclosed. For instance, a filled amorphous bag apparatus for positioning screened devices, the apparatus may consist essentially of or consist of at least one amorphous bag, a malleable filling within the amorphous bag and at least one first connector on or within the amorphous bag.

In another non-limiting embodiment a filled amorphous bag apparatus for positioning screened devices, the apparatus consisting essentially of or consisting of at least one amorphous bag, a malleable filling within the amorphous bag and at least one first connector that is a recess to receive within the amorphous bag, where the armature is configured to be adjustable and positionable, and the armature comprises at least one second connector.

In another non-restrictive version there may be provided a filled amorphous bag apparatus for positioning screened devices, the apparatus consisting essentially of or consisting of at least one amorphous bag, a malleable filling within the amorphous bag, and at least one rigid armature comprising at least one first connector.

In a different, non-limiting embodiment a multi-component system for positioning screened devices is provided where the multi-component system consists essentially of or consists of at least one mounting component configured to mount to a case of a screened device bearing a screen, the mounting component comprising a magnetic surface and a filled amorphous bag apparatus for positioning screened devices, the apparatus consisting essentially of or consisting of at least one amorphous bag, a malleable filling within the amorphous bag, and at least one magnet on or within the amorphous bag.

In further non-restrictive method for positioning a screened device, the method consists essentially of or consists of attaching a filled amorphous bag apparatus to the screened device, where the filled amorphous bag apparatus consists essentially of or consists of at least one amorphous bag, a malleable filling within the amorphous bag, and at least one first connector on or within the amorphous bag, where the method also consists essentially of or consists of adjusting the filled amorphous bag apparatus to position the screened device.

The words “comprising” and “comprises” as used throughout the claims, are to be interpreted to mean “including but not limited to” and “includes but not limited to”, respectively.

What is claimed is:

1. A filled amorphous bag apparatus for positioning screened devices, the apparatus comprising:
at least one amorphous bag;
a malleable filling within the amorphous bag; and
at least one first connector on or within the amorphous bag.

2. The filled amorphous bag apparatus of claim 1 where the malleable filling is selected from the group consisting of a plurality of pellets, a putty, a gel, a stuffing, and combinations thereof.

3. The filled amorphous bag apparatus of claim 1 where the at least one first connector is selected from the group consisting of at least one magnet, a plurality of hooks, a plurality of loops, a suction cup, one half of a snap, a clip, a clamp, a clasp, adhesive, at least one recess, and combinations of these.

4. The filled amorphous bag apparatus of claim 1 where the malleable filling comprises a plurality of pellets, and where the at least one first connector are the plurality of pellets and where at least a portion of the plurality of pellets are selected from the group consisting of non-magnetic ferrimagnetic material, non-magnetic ferromagnetic material, magnetic ferrimagnetic material, non-magnetic ferromagnetic material and combinations thereof.

5. The filled amorphous bag apparatus of claim 1 further comprising a generally cylindrical shape.

6. The filled amorphous bag apparatus of claim 5 where the at least one amorphous bag has a first end and a second end, where the at least one amorphous bag has an average diameter, and where at least one end is a rigid end cap with a dimension greater than the average diameter of the at least one amorphous bag.

7. The filled amorphous bag apparatus of claim 6 where the at least one amorphous bag has a first end that is flat and a second end that is not flat.

8. The filled amorphous bag apparatus of claim 7 where the flat end has a weight.

9. The filled amorphous bag apparatus of claim 1 where the at least one first connector is a magnet affixed to the amorphous bag.

10. The filled amorphous bag apparatus of claim 1 further comprising at least one stabilizing protrusion configured help the pellet-filled amorphous bag apparatus maintain an orientation.

11. The filled amorphous bag apparatus of claim 1 where the at least one first connector comprises at least one recess to receive an armature within the amorphous bag, where the armature is configured to be adjustable and positionable, and the armature comprises at least one second connector.

12. The filled amorphous bag apparatus of claim 1 where the pellet-filled amorphous bag apparatus is configured to be received within a cup holder.

13. The filled amorphous bag apparatus of claim 1 further comprising at least one receptacle.

14. The filled amorphous bag apparatus of claim 13 where the receptacle is a pocket.

15. The filled amorphous bag apparatus of claim 1 where the at least one amorphous bag at least partially comprises a screen cleaning material.

16. The filled amorphous bag apparatus of claim 1 where the at least one amorphous bag at least partially comprises a duster selected from the group consisting of a brush, a feather duster, and combinations thereof.

17. The filled amorphous bag apparatus of claim 1 further comprising a covering spaced apart from the at least one amorphous bag, where the at least one first connector is a magnet free to move around the surface of at least one amorphous bag between the at least one amorphous bag and the covering.

18. The filled amorphous bag apparatus of claim 1 further comprising a spherical shape.

19. The filled amorphous bag apparatus of claim 1 further comprising a hemispherical shape and a flat base.

20. The pellet-filled amorphous bag apparatus of claim 1 where the at least one amorphous bag is impervious to water.

21. The filled amorphous bag apparatus of claim 1 further comprising an electrically conductive feature selected from the group consisting of the plurality of pellets and the at least one amorphous bag, and the at least one first connector is configured to electrically connect a mobile device to the electrically conductive feature to enhance the antenna of the mobile device.

22. The filled amorphous bag apparatus of claim 1 where the malleable filling comprises a plurality of pellets, and the at least one first connector are the plurality of pellets and where at least a portion of the plurality of pellets are selected from the group consisting of magnetic ferromagnetic material, non-magnetic ferromagnetic material, magnetic ferrimagnetic material, non-magnetic ferrimagnetic material, and combinations thereof.

23. The filled amorphous bag apparatus of claim 22 further comprising an amorphous, malleable putty or gel within the at least one amorphous bag, where the plurality of pellets are within the amorphous, malleable putty or gel.

24. The filled amorphous bag apparatus of claim 1 further comprising at least one strap.

25. The filled amorphous bag apparatus of claim 24 further comprising at least two straps configured to be connectable to one another employing fasteners selected from the group consisting of the strap ends, at least one magnet, a combination of a plurality of hooks and a plurality of loops, a suction cup, a snap, a clip, a clamp, a clasp, adhesive, and combinations of these.

26. The filled amorphous bag apparatus of claim 1 designed to be or resemble an item selected from the group consisting of a toy, a figure, a figurine, a mascot, a creature, an object, a doll, an action figure, a logo, a design, a person, a fictional creature, a fictional person, a fictional object, and combinations thereof.

27. A filled amorphous bag apparatus for positioning screened devices, the apparatus comprising:
at least one amorphous bag;
a malleable filling within the amorphous bag; and
at least one first connector that is a recess to receive an armature within the amorphous bag, where the armature is configured to be adjustable and positionable, and the armature comprises at least one second connector.

28. A filled amorphous bag apparatus for positioning screened devices, the apparatus comprising:
at least one amorphous bag;
a malleable filling within the amorphous bag; and
at least one rigid armature comprising at least one first connector.

29. The filled amorphous bag apparatus of claim 28 where the rigid armature comprises a first end and a second end, where the first end is affixed to the at least one amorphous bag which is a first amorphous bag, and where the second end is affixed to at least one second amorphous bag.

30. A multi-component system for positioning screened devices, the multi-component system comprising:
at least one mounting component configured to mount to a case of a screened device bearing a screen, the mounting component comprising a magnetic surface; and
a filled amorphous bag apparatus for positioning screened devices, the apparatus comprising:
at least one amorphous bag;
a malleable filling within the amorphous bag; and
at least one magnet on or within the amorphous bag.

31. The multi-component system of claim 30 where the magnetic surface and the magnetic selectively couple via a magnetic attractive force.

32. The multi-component system of claim 30 where in the filled amorphous bag apparatus the magnet comprises at least a portion of the malleable filling.

33. A method for positioning a screened device, the method comprising:
attaching a filled amorphous bag apparatus to the screened device, where the filled amorphous bag apparatus comprises:
at least one amorphous bag;
a malleable filling within the amorphous bag; and
at least one first connector on or within the amorphous bag;
adjusting the filled amorphous bag apparatus to position the screened device.

34. The method of claim 33 where the at least one first connector is selected from the group consisting of a magnet, a plurality of hooks, a plurality of loops, a suction cup, one half of a snap, a clip, a clamp, a clasp, adhesive, at least one recess, and combinations of these, and where the method further comprises selectively coupling the at least one first connector to at least one second connector on the screened device.
